(19) United States
(12) Patent Application Publication
(10) Pub. No.: US 2016/0276513 A1
(43) Pub. Date: Sep. 22, 2016

(54) PHOTOVOLTAIC CELL MODULE, PHOTOVOLTAIC CELL MODULE PACKAGE AND VEHICLE INCLUDING THE SAME

(71) Applicants: KABUSHIKI KAISHA TOYOTA JIDOSHOKKI, Kariya-shi (JP); TOYOTA JIDOSHA KABUSHIKI KAISHA, Aichi-ken (JP)

(72) Inventors: Hirotaka INABA, Kariya-shi (JP); Kazutaka KIMURA, Susono-shi (JP); Yuki KUDO, Susono-shi (JP)

(73) Assignees: KABUSHIKI KAISHA TOYOTA JIDOSHOKKI, Kariya-shi (JP); TOYOTA JIDOSHA KABUSHIKI KAISHA, Aichi-ken (JP)

(21) Appl. No.: 15/070,142

(22) Filed: Mar. 15, 2016

(30) Foreign Application Priority Data
Mar. 16, 2015 (JP) 2015-051678

(51) Int. Cl. H01L 31/048

(52) U.S. Cl. CPC H01L 31/0488

(57) ABSTRACT

The photovoltaic cell module includes a plate-shaped first cover, a second cover disposed to face the first cover, a photovoltaic cell disposed between the first cover and the second cover, and a sealing member. The second cover includes a plate-shaped portion and a protruding portion protruding from at least a part of an outer edge of the plate-shaped portion toward the first cover. The plate-shaped portion includes a transparent portion disposed at a position facing at least the photovoltaic cell. When viewed in the thickness direction of the first cover, at least a part of the protruding portion is located outside the outer edge of the first cover. An end face of the protruding portion located furthest from the plate-shaped portion in the thickness direction of the first cover is flush with a virtual plane including therein one surface of the first cover distant from the second cover.

This non-provisional application is based on Japanese Patent Application No. 2015-051678 filed on Mar. 16, 2015 with the Japan Patent Office, the entire contents of which are hereby incorporated by reference.

### BACKGROUND OF THE INVENTION

1. Field of the Invention

The present invention relates to a photovoltaic cell module, a photovoltaic cell module package and a vehicle including the same.

2. Description of the Background Art

As a prior art document disclosing the configuration of the photovoltaic cell module, Japanese Patent Laying-Open No. 2014-75464 may be given. The photovoltaic cell module disclosed in Japanese Patent Laying-Open No. 2014-75464 includes a transparent light-receiving panel, and a light non-receiving panel, a photovoltaic cell string, a silicone gel sheet, and butyl rubber. The photovoltaic cell string is disposed between the transparent light-receiving panel and the tight non-receiving panel, and is sealed by using the silicone gel sheet. The transparent light-receiving panel and the light non-receiving panel are pressed by using butyl rubber which is formed into a frame shape.

In the case where the photovoltaic cell module is fabricated in a manner of being pressed by butyl rubber, the thickness of the photovoltaic cell module may vary relatively large due to the variation in the thickness of the butyl rubber and the variation in the elasticity thereof.

### SUMMARY OF THE INVENTION

A main objective of the present invention is to provide a photovoltaic cell module with the variation in the thickness thereof being reduced, a photovoltaic cell module package and a vehicle including the same.

The photovoltaic cell module according to a first aspect of the present invention includes a plate-shaped first cover, a second cover disposed to face the first cover, a photovoltaic cell disposed between the first cover and the second cover, and a sealing member filled between the first cover and the second cover so as to bond the same to each other and seal the photovoltaic cell. The second cover includes a plate-shaped portion and a protruding portion protrading from at least a part of an outer edge of the plate-shaped portion toward the first cover. The plate-shaped portion includes a transparent portion disposed at a position facing at least the photovoltaic cell. When viewed in the thickness direction of the first cover, at least a part of the protruding portion is located outside the outer edge of the first cover. An end face of the protruding portion located furthest from the plate-shaped portion in the thickness direction of the first cover is flush with a virtual plane including therein one surface of the first cover distant from the second cover.

The photovoltaic cell module package according to a second aspect of the present invention includes the photovoltaic cell module mentioned above, supporting member for supporting the photovoltaic cell module, and a bonding member for bonding the photovoltaic cell module and the supporting member together. The bonding member is disposed between a first cover side of the photovoltaic cell module and the supporting member so as to cover a gap between the first cover and the protruding portion.

The vehicle according to a third aspect of the present invention includes the photovoltaic cell module package mentioned above, and the supporting member is a part of the vehicle body.

According to the present invention, the variation in thickness of the photovoltaic cell module can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view illustrating the outer appearance of a vehicle according to Embodiment 1 of the present invention.

FIG. 2 is a plan view illustrating the outer appearance of a photovoltaic cell module provided in the vehicle according to Embodiment 1 of the present invention, which is viewed from the direction of arrow II in FIG. 1.

FIG. 3 is a cross-sectional view illustrating a photovoltaic cell module package provided in the vehicle according to Embodiment 1 of the present invention, which is viewed from the arrow direction of line III-III in FIG. 1.

FIG. 4 is an exploded sectional view illustrating components of the photovoltaic cell module according to Embodiment 1 of the present invention.

FIG. 5 is a cross-sectional view illustrating a state where the components of the photovoltaic cell module according to Embodiment 1 of the present invention are vacuum bonded.

FIG. 6 is a cross-sectional view illustrating a photovoltaic cell module package provided in the vehicle according to Embodiment 2 of the present invention.

FIG. 7 is a cross-sectional view illustrating a photovoltaic cell module package provided in the vehicle according to Embodiment 3 of the present invention.

### DESCRIPTION OF THE PREFERRED EMBODIMENTS

Hereinafter, a photovoltaic cell module, a photovoltaic cell module package and a vehicle including the photovoltaic cell module package according to each embodiment of the present invention will be described with reference to the drawings. It should be noted that in the following description, the same or equivalent portions in the drawings will be denoted by the same reference signs, and the description thereof will not be repeated.

### Embodiment 1

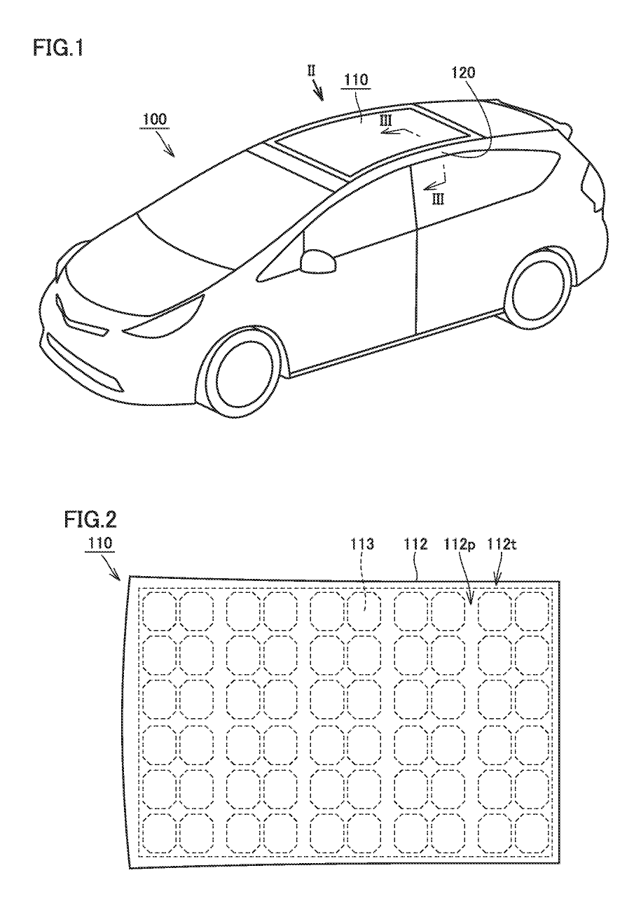

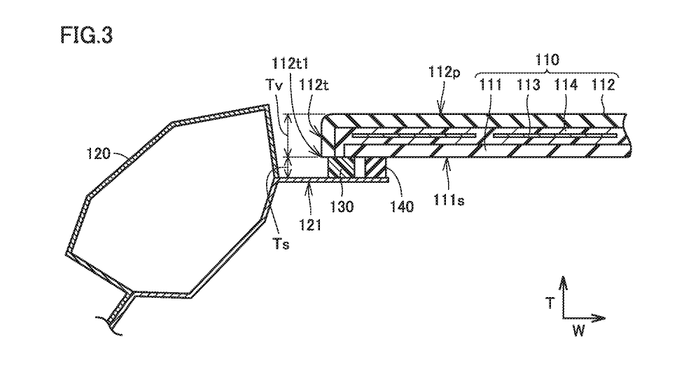

FIG. 1 is a perspective view illustrating the outer appearance of a vehicle according to Embodiment 1 of the present invention. FIG. 2 is a plan view illustrating the outer appearance of a photovoltaic cell module provided in the vehicle according to Embodiment 1 of the present invention, which is viewed from the direction of arrow IT in FIG. 1. FIG. 3 is a cross-sectional view illustrating a photovoltaic cell module package provided in the vehicle according to Embodiment 1 of the present invention, which is viewed from the arrow direction of line III-III in FIG. 1.

As illustrated in FIGS. 1 to 3, a vehicle 100 according to Embodiment 1 of the present invention is a motor vehicle provided with a photovoltaic cell module 110 which constitutes a roof and a roof side member 120 which is a part of the vehicle body. The vehicle is not limited to a motor vehicle, it may be an electric vehicle, for example.

The photovoltaic cell module 110 includes a plate-shaped first cover 111, a second cover 112 that is disposed to face the first cover 111, a photovoltaic cell 113 that is disposed between the first cover 111 and the second cover 112, a sealing member 114 that is filled between the first cover 111 and the second cover 112 so as to bond the two covers to each other and seal the photovoltaic cell 113.

The first cover 111 has a substantially rectangular shape in planar view. In the present embodiment, the first cover 111 is a flat plate, but it may be curved. In the present embodiment, the first cover 111 is a plate made of polycarbonate. However, the first cover 111 is not limited thereto, it may be a plate made of resin such as acrylic resin, or a plate made of CFRP (carbon-fiber-reinforced plastics), a plate made of metal such as aluminum or a sheet made of resin such as polyethylene terephthalate. In FIG. 3, the reference sign T denotes the thickness direction of the first cover 111, and the reference sign W denotes the width direction thereof.

The second cover 112 includes a plate-shaped portion 112p having a substantially rectangular shape in planar view. The plate-shaped portion 112p is flat in the present embodiment, and however, in the case where the first cover 111 is curved, the plate-shaped portion 112p may be curved with substantially the same curvature as the first cover 111. In the present embodiment, a protruding portion 112t is provided to protrude from the outer edge of the plate-shaped portion 112p toward the first cover 111 along the entire circumference of the outer edge of the plate-shaped portion 112p. In other words, the protruding portion 112t is formed as a continuous frame of a substantially rectangular shape along the entire circumference.

However, the configuration of the protruding portions 112t is not limited to that mentioned in the above, it may protrude from at least a part of the outer edge of the plate-shaped portion 112p toward the first cover 111. For example, four of the protruding portions 112t may be provided respectively along four sides of the substantially rectangular shape of the outer edge of the plate-shaped portion 112p, spacing apart from each other. In this case, a portion such as butyl rubber is disposed at each spacing between adjacent protruding portions 112t so as to prevent the sealing portion from flowing out.

In the present embodiment, when viewed in the thickness direction of the first cover 111, the protruding portion 112t is located outside the outer edge of the first cover 111. In other words, when viewed in the thickness direction of the first cover 111, the protruding portion 112t and the first cover 111 do not overlap with each other. However, the positional relationship between the protruding portion 112t and the first cover 111 is not limited to that mentioned in the above, it is acceptable that at least a part of the protruding portion 112t is located outside the outer edge of the first cover 111 when viewed in the thickness direction of the first cover 111.

Owing to the disposition of a gap between the protruding portion 112t and the first cover 111, it is possible to prevent the first cover 111 and the second cover 112 from interfering with each other due to the variation in the dimensions of each of the first cover 111 and the second cover 112 and the difference between the thermal expansion coefficients thereof. It should be noted that the gap provided between the protruding portion 112t and the first cover 111 is not indispensable.

An end face 112t1 of the protruding portion 112t located furthest from the plate-shaped portion 112p in the thickness direction of the first cover 111 is flush with a virtual plane including therein one surface 111s of the first cover 111 distant from the second cover 112. The virtual plane is a flat plane in the present embodiment, and however, in the case where the first cover 111 is curved, the virtual plane may be a curved one.

In the present embodiment, the second cover 112 is a plate made of polycarbonate. However, the second cover 112 is not limited thereto, and it may be a plate made of resin such as acrylic resin The second cover 112 is formed by injection-molding transparent polycarbonate, and thereby, the plate-shaped portion 112p and the protruding portion 112t are formed integrally.

The plate-shaped portion 112p in a whole serves as a transparent portion that transmits light. However, the configuration of the plate-shaped portion 112p is not limited to that mentioned in the above, it is acceptable that the transparent portion is disposed at a position facing at least the photovoltaic cell 113. In other words, those portions in the plate-shaped portion 112p that are not facing the photovoltaic cell 113 may be provided as a light-shielding portion made of an opaque material.

The photovoltaic cells 113 are disposed in plural into a matrix with an interval spacing each other. The plurality of photovoltaic cells 113 are electrically connected to each other. Specifically, the plurality of photovoltaic cells 113 are connected in series to each other to constitute a plurality of photovoltaic cell strings, and the plurality of photovoltaic cell strings are connected in parallel to each other.

The sealing member 114 is disposed in a space sandwiched between the first cover 111 and the second cover 112, and a part of the sealing member 114 disposed in the gap between the outer edge of the first cover 111 and the protruding portion 112t is exposed out of a first cover 111 side of the photovoltaic cell module 110. In the present embodiment, as viewed from the first cover 111 side of the photovoltaic cell module 110, the exposed portion of the sealing member 114 has a substantially rectangular shape.

In the present embodiment, the sealing member 114 is made of EVA (Ethylene-Vinyl Acetate). However, the material constituting the sealing member 114 is not limited to EVA, it may be PVB (Poly Vinyl Butyral) resin, silicone resin or ionomer resin.

Hereinafter, a method for manufacturing the photovoltaic cell module 110 will be described.

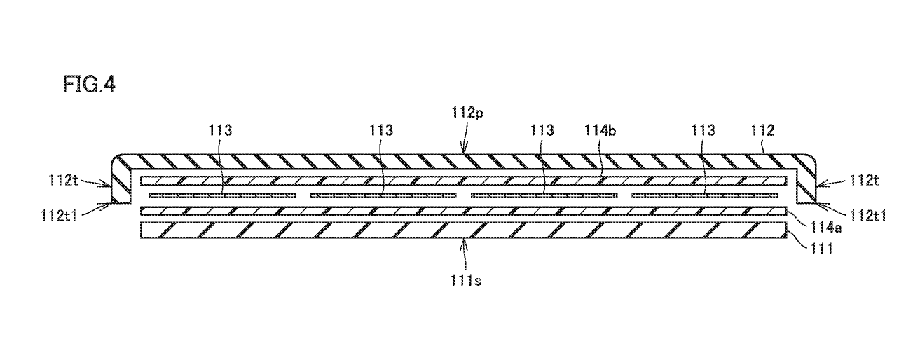

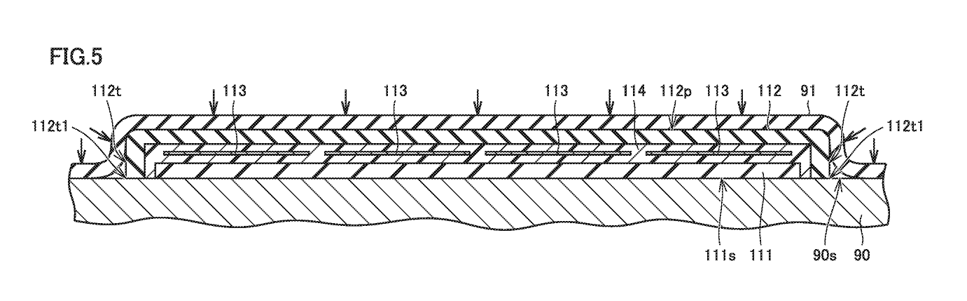

FIG. 4 is an exploded sectional view illustrating the components of the photovoltaic cell module according to Embodiment 1 of the present invention. FIG. 5 is a cross-sectional view illustrating a state where the components of the photovoltaic cell module according to Embodiment 1 of the present invention are vacuum bonded.

As illustrated in FIG. 4, a first sheet 114a made of EVA is disposed on the first cover 111. Next, a plurality of photovoltaic cells 113 are aligned on the first sheet 114a. Subsequently, a second sheet 114b is disposed to cover the plurality of photovoltaic cells 113. Thereafter, the second cover 112 is disposed in such a manner that the plate-shaped portion 112p is placed on the second sheet 114b and the first cover 111 is located inside the substantially rectangular region surrounded by the protruding portion 112t.

The laminated body laminated as described above is sealed by using a vacuum laminator. More specifically, as illustrated in FIG. 5, the laminated body is placed on a heating plate 90 in the chamber of the vacuum laminator. A surface 90s of the heating plate 90 in the present embodiment is a flat plane, and however, in the case where the first cover 111 is curved, it may be a curved face with substantially the same curvature as the first cover 111. While the laminated body is being heated by the heating plate 90, the chamber is evacuated so as to pressurize the laminated body by using a diaphragm 91 to press the laminated body against the heating plate 90 in accordance with a pressure difference along the direction illustrated by the arrows. After being heated, the first sheet 114a and the second sheet 114b melt, and thereby flow as a fluid to fill the space between the first cover 111 and the second cover 112 and become integral with the first cover 111 and the second cover 112.

As the first sheet 114a and the second sheet 114b are melted to flow as a fluid, the second cover 112 moves toward the heating plate 90, and thereby, the plate-shaped portion 112p of the second cover 112 approaches to the first cover 111. When the end face 112t1 of the protruding portion 112t of the second cover 112 is in contact with the surface 90s of the heating plate 90, the movement of the second cover 112 is stopped.

At this moment, the heating of the laminated body by the heating plate 90 is stopped, and the melted EVA solidifies, thereby sealing the plurality of photovoltaic cells 113 and meanwhile bonding the first cover 111 and the second cover 112 together.

As a result, the first cover 111 and the second cover 112 are bonded together, with the end face 112t1 of the protruding portion 112t in flush with the virtual plane including therein the surface 111s of the first cover 111 distant from the second cover 112.

The amount of EVA included in each of the first sheet 114a and the second sheet 114b may be adjusted in such manner that the amount of EVA is just suitable to be filled between the first cover 111 and the second cover 112 so as to bond the first cover 111 and second cover 112 together as described above.

As illustrated in FIG. 3, the thickness Tv of the photovoltaic cell module 110 manufactured as described above is the same as the height of the second cover 112 in the thickness direction T of the first cover 111. In other words, the thickness Tv of the photovoltaic cell module 110 is determined by the height of the second cover 112. The variation in the height of the second cover 112 is determined by the dimensional accuracy in molding the second cover 112, and thereby is relatively small. Therefore, in the photovoltaic cell module 110 according to the present embodiment, the variation in the thickness of the photovoltaic cell module 110 can be reduced.

As illustrated in FIG. 3, in the package of the photovoltaic cell module 110 according to the present embodiment, the photovoltaic cell module 110 is mounted on a flange 121, namely a supporting member, which is a part of the roof side member 120. Specifically, the photovoltaic cell module 110 is mounted on a spacer 140 disposed on the flange 121. The surface 111s of the first cover 111 distant from the second cover 112 is in contact with the spacer 140. The spacer 140 is formed of a rigid body having an insulating property.

The photovoltaic cell module 110 and the flange 121 are bonded together by a bonding member 130. The bonding member 130 is disposed between the first cover 111 side of the photovoltaic cell module 110 and the flange 121 so as to cover the gap between the protruding portion 112t and the first cover 111. In other words, the bonding member 130 is formed into a frame having a substantially rectangular shape.

When bonding the photovoltaic cell module 110 and the flange 121, the plate-shaped portion 112p is being pressed toward the flange 121. As a result, the spacer 140 is sandwiched between the first cover 111 and the flange 121.

The bonding member 130 is configured to exert a bonding force to each of the photovoltaic cell module 110 and the flange 121 so as to make the photovoltaic cell modules 110 and the flange 121 approach each other. In the present embodiment, the bonding member 130 is an adhesive containing urethane resin. However, the bonding member 130 is not limited thereto, and it may be an adhesive containing epoxy resin or the like.

As described in the above, since the photovoltaic cell module 110 and the flange 121 are bonded to each other by the bonding member 130 and the exposed sealing member 114 is covered by the bonding member 130, it is possible to ensure water resistance to the photovoltaic cell module 110.

As illustrated in FIG. 3, the distance Ts between the photovoltaic cell module 110 mounted on the flange 121 as described above and the flange 121 is the same as the thickness of the spacer 140. In other words, the distance Ts between the photovoltaic cell module 110 and the flange 121 is determined by the thickness of the spacer 140. The variation in the thickness of the spacer 140 is determined by the dimensional accuracy in molding the spacer 140, and thereby is relatively small.

The height from the flange 121 to the upper surface of the photovoltaic cell module 110 is the sum of the distance Ts between the photovoltaic cell module 110 and the flange 121 and the thickness Tv of the photovoltaic cell module 110.

As described above, since the thickness Tv of the photovoltaic cell module 110 is determined by the height of the second cover 112 and the distance Ts between the photovoltaic cell module 110 and the flange 121 is determined by the thickness of the spacer 140, it is possible to reduce the height variation in the upper surface of the photovoltaic cell module 110 in the vehicle 100 according to the present embodiment.

In order to achieve a high aesthetic design in a vehicle, it is important to reduce the height variation in the upper surface of the photovoltaic cell module 110 constituting the roof. Since the vehicle 100 according to the present embodiment includes the package structure of the photovoltaic cell module 110, it meets the high aesthetic design requirement.

In the present embodiment, the supporting member is the flange 121 that is a part of the roof side member 120, but the supporting member is not limited thereto, and it may be for example a roof of a garage, an arcade of a building or the like. In a package structure of the photovoltaic cell module 110 mounted on a roof of a garage, an arcade of a building or the like, it is possible to reduce the height variation in the upper surface of the photovoltaic cell module 110.

According to the present embodiment, since it is unnecessary to dispose butyl rubber as required in the conventional photovoltaic cell module, it is possible to reduce the number of components, thereby reduce the cost and time required to manufacture the photovoltaic cell module.

### Embodiment 2

Hereinafter, a photovoltaic cell module, a photovoltaic cell module package and a vehicle including the photovoltaic cell module package according to Embodiment 2 of the present invention will be described. Note that the photovoltaic cell module 210 according to the present embodiment is different from the photovoltaic cell module 110 according to Embodiment 1 only in the forming method of the second cover, the description for the other components will not be repeated.

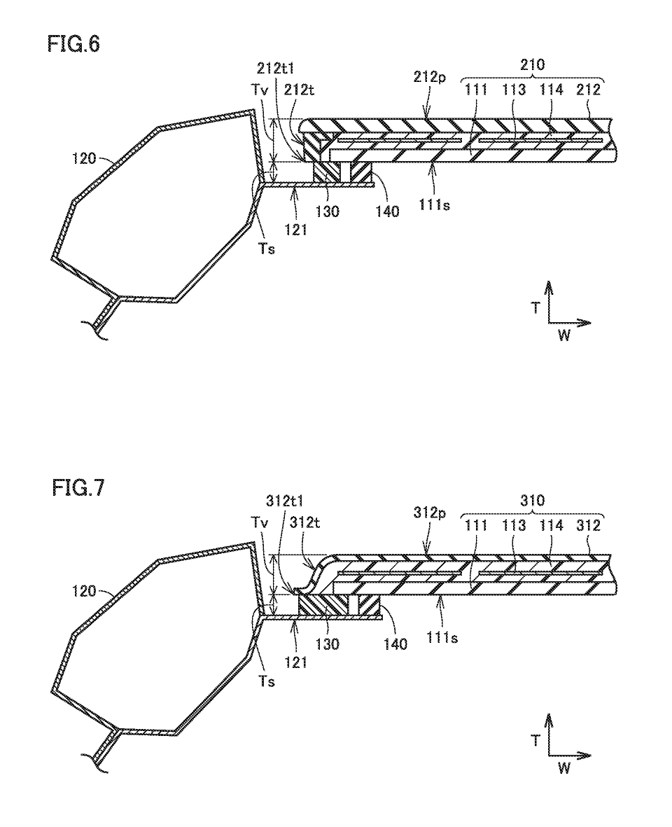

FIG. 6 is a sectional view illustrating a photovoltaic cell module package provided in the vehicle according to Embodiment 2 of the present invention. The cross-sectional view in FIG. 6 is the same as that in FIG. 3.

The second cover 212 of the photovoltaic cell module 210 provided in the vehicle according to Embodiment 2 of the present invention is formed according to a two-color molding method. As illustrated in FIG. 6, the second cover 212 includes a plate-shaped portion 212p having a substantially rectangular shape in planar view and a protruding portion 212t protruding from the outer edge of the plate-shaped portion 212p toward the first cover 111.

The plate-shaped portion 212p is made of transparent polycarbonate. The protruding portion 212t is made of opaque polycarbonate. For example, the protruding portion 212t is made in black color However, the material of each of the plate-shaped portion 212p and the protruding portion 212t is not limited to polycarbonate, it may be any resin such as acrylic resin.

In the present embodiment, a part of the protruding portion 212t overlaps with the outer edge of the first cover 111 as viewed in the thickness direction of the first cover 111. Thus, as viewing the photovoltaic cell module package of the photovoltaic cell module 210 from a second cover 212 side, the bonding member 130 is invisible. As a result, it is possible to improve the aesthetic design of the vehicle.

The other portion of the protruding portion 212t is located outside the outer edge of the first cover 111 when viewed in the thickness direction of the first cover 111. The end face 112t1 of the other portion of the protruding portion 112t located furthest from the plate-shaped portion 212p in the thickness direction T of the first cover 111 is flush with the virtual plane including therein the surface 111s of the first cover 111 distant from the second cover 212.

In the photovoltaic cell module 210 according to the present embodiment, it is also possible to reduce the variation in the thickness of the photovoltaic cell module 210. Similarly, in the package structure of the photovoltaic cell module 210 and a vehicle including the same according to the present embodiment, it is possible to reduce the height variation in the upper surface of the photovoltaic cell module 210.

### Embodiment 3

Hereinafter, a photovoltaic cell module, a photovoltaic cell module package and a vehicle including the photovoltaic cell module package according to Embodiment 3 of the present invention will be described. Note that the photovoltaic cell module 310 according to the present embodiment is different from the photovoltaic cell module 110 according to Embodiment 1 only in the forming method of the second cover, the description for the other components will not be repeated.

FIG. 7 is a sectional view illustrating a photovoltaic cell module package provided in the vehicle according to Embodiment 3 of the present invention. The cross-sectional view in FIG. 7 is the same as that in FIG. 3.

The second cover 312 of the photovoltaic cell module 310 provided in the vehicle according to Embodiment 3 of the present invention is formed according to a vacuum molding method. As illustrated in FIG. 7, the second cover 312 includes a plate-shaped portion 312p having a substantially rectangular shape in planar view and a protruding portion 312t protruding from the outer edge of the plate-shaped portion 312p toward the first cover 111.

The second cover 312 is made of transparent polycarbonate. However, the material of the second cover 312 is not limited to polycarbonate, and it may be any resin such as acrylic resin.

In the present embodiment, the protruding portion 312t does not overlap with the outer edge of the first cover 111 when viewed in the thickness direction of the first cover 111. The protruding portion 312t is configured to spread away from the outer edge of the first cover 111 as approaching toward the first cover 111 along the thickness direction T of the first cover 111.

The end face 312t1 of the protruding portion 312t located farthest from the plate-shaped portion 312p in the thickness direction T of the first cover 111 is flush with the virtual plane including therein the surface 111s of the first cover 111 distant from the second cover 312.

In the photovoltaic cell module 310 according to the present embodiment, it is also possible to reduce the variation in the thickness of the photovoltaic cell module 310. Similarly, in the package structure of the photovoltaic cell module 310 and a vehicle including the same according to the present embodiment, it is possible to reduce the height variation in the upper surface of the photovoltaic cell module 310.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A photovoltaic cell module comprising:
a plate-shaped first cover;
a second cover disposed to face the first cover;
a photovoltaic cell disposed between the first cover and the second cover; and
a sealing member filled between the first cover and the second cover so as to bond the same to each other and seal the photovoltaic cell,
the second cover including a plate-shaped portion and a protruding portion protruding from at least a part of an outer edge of the plate-shaped portion toward the first cover,
the plate-shaped portion including a transparent portion disposed at a position facing at least the photovoltaic cell,
when viewed in the thickness direction of the first cover, at least a part of the protruding portion being located outside the outer edge of the first cover, and
an end face of the protruding portion located furthest from the plate-shaped portion in the thickness direction of the first cover being flush with a virtual plane including therein one surface of the first cover distant from the second cover.

2. The photovoltaic cell module according to claim 1, wherein the protruding portion is opaque.

3. The photovoltaic cell module according to claim 1, wherein the protruding portion is provided along the entire circumference of the outer edge of the plate-shaped portion.

4. A photovoltaic cell module package comprising:
the photovoltaic cell module according to claim 1;
a supporting member for supporting the photovoltaic cell module; and
a bonding member for bonding the photovoltaic cell module and the supporting member together,
the bonding member being disposed between a first cover side of the photovoltaic cell module and the supporting member so as to cover a gap between the first cover and the protruding portion.

5. A vehicle including the photovoltaic cell module package according to claim 4, wherein the supporting member is a part of the vehicle body.
